(19) United States
(12) Patent Application Publication
(10) Pub. No.: US 2014/0187112 A1
(43) Pub. Date: Jul. 3, 2014

(54) PREPREG, METHOD FOR MANUFACTURING THE SAME, AND COPPER CLAD LAMINATE USING THE SAME

(71) Applicant: SAMSUNG ELECTRO-MECHANICS CO., LTD., Suwon-si (KR)

(72) Inventors: Sang Hyun Shin, Suwon-si (KR); Joon Seok Kang, Suwon-si (KR); Jang Bae Son, Suwon-si (KR); Kwang Jik Lee, Suwon-si (KR); Hye Sook Shin, Suwon-si (KR); Hyun Chul Jung, Suwon-si (KR)

(73) Assignee: SAMSUNG ELECTRO-MECHANICS CO., LTD., Suwon-si (KR)

(21) Appl. No.: 14/140,160

(22) Filed: Dec. 24, 2013

(30) Foreign Application Priority Data
Dec. 28, 2012 (KR) 10-2012-0157124

(51) Int. Cl. H05K 1/03; H05K 3/00; H05K 1/05

(52) U.S. Cl. CPC H05K 1/0366; H05K 1/05; H05K 3/0055
USPC 442/164; 442/172; 442/175; 442/180; 442/232; 427/97.6

(57) ABSTRACT

Disclosed herein are a prepreg, including: an inorganic fiber, an organic fiber, or a hybrid fiber obtained by mix-weaving the inorganic fiber and the organic fiber, coated with a thermally conductive component or impregnated with a thermally conductive component; and a cross-linkable resin for impregnating the fiber therewith, a method for manufacturing the same, and a copper clad laminate using the same, so that the prepreg and the copper clad laminate can maintain a low coefficient of thermal expansion and a high modulus of elasticity and have excellent heat radiation property.

### CROSS REFERENCE TO RELATED APPLICATION

This application claims the benefit of Korean Patent Application No. 10-2012-0157124, filed on Dec. 28, 2012, entitled “Prepreg, Method for Manufacturing the Same, and Copper Clad Laminate Using the Same”, which is hereby incorporated by reference in its entirety into this application.

### BACKGROUND OF THE INVENTION

1. Technical Field

The present invention relates to a prepreg, a method for manufacturing the same, and a copper clad laminate using the same.

2. Description of the Related Art

With the development of electronic devices and request for complicated functions, a printed circuit board has continuously been required to have a low weight, a thin thickness, and a small size. In order to satisfy these requests, the wirings of the printed circuit board have become more complex, further densified, and higher functioned.

As such, as the electronic device has a smaller size and a higher function, a multilayer printed circuit board is requested to become further densified, higher functioned, smaller, and thinner. Particularly, the multilayer printed circuit board has been developed to have finer and higher densified wirings. For this reason, thermal, mechanical, and electric properties become important in an insulating layer of the multilayer printed circuit board. In order to minimize warpage occurring due to reflow in a procedure of mounting electronic and electric devices, a low coefficient of thermal expansion (CTE), a high glass transition temperature (Tg), and a high modulus are required.

As an insulating substrate applied to a general printed circuit board, a prepreg obtained by impregnating a reinforced glass fiber with a binder and then drying it, and a copper clad laminate manufactured by overlapping a predetermined number of sheets of prepreg and then stacking a copper foil thereon have been used Generally, the prepreg is manufactured by impregnating a glass fiber with a cross-linkable resin such as epoxy or the like. However, a prepreg having a glass fiber impregnated, which is manufactured through the foregoing method, may be easily deformed and disconnected due to a high coefficient of thermal expansion, and thus, it is impossible to develop a high value prepreg.

Meanwhile, the printed circuit board fundamentally serves to connect various kinds of electronic components to a mother board for a printed circuit board according to the circuit design of electric wirings or support the electronic components. However, as the number of mounted passive components and packaging components are increased, more power is consumed and higher heat is generated in the electronic components. Accordingly, heat radiation performance is an important standard for determining in view of reliability of products and consumer product preference.

Patent Document 1 discloses that a prepreg including a hybrid textile composed of an inorganic fiber and an organic fiber has excellent high-temperature reliability, but the hybrid textile has problems in a manufacturing process and is unfavorable in economical feasibility. Patent Document 1: Korean Patent Laid-Open Publication No. 2012-0072644

### SUMMARY OF THE INVENTION

The foregoing problems can be simply and economically solved by coating a glass fiber used as a reinforcing agent of a prepreg for a printed circuit board with a component having excellent thermal conductivity, based on which the present invention was completed.

The present invention has been made in an effort to provide a prepreg having excellent thermal conductivity.

Further, the present invention has been made in an effort to provide a method for manufacturing the prepreg.

Still further, the present invention has been made in an effort to provide a copper clad laminate in which a copper foil is laminated on the prepreg.

According to a preferred embodiment of the present invention, there is provided a prepreg, including: an inorganic fiber, an organic fiber, or a hybrid fiber obtained by mix-weaving the inorganic fiber and the organic fiber, coated with a thermally conductive component or impregnated with a thermally conductive component; and a cross-linkable resin for impregnating the fiber therewith.

The thermally conductive component may be Al₂O₃, BN, AlN, SiO₂, or a mixture thereof.

Here, a coating thickness may be 100 nm˜10 μm.

The inorganic fiber may be a glass fiber.

The organic fiber may be at least one of a carbon fiber, a poly-para-phenylenebenzoatebisoxazole fiber, a thermotropic liquid crystal polymer fiber, a lysotropic liquid crystal polymer fiber, an aramid fiber, a polypyridobismidazole fiber, a polybenzothiazole fiber, and a polyarylate fiber.

The cross-linkable resin may be at least one epoxy resin selected from a naphthalene epoxy resin, a bisphenol A epoxy resin, a phenol novolac epoxy resin, a cresole novolac epoxy resin, a rubber modified epoxy resin, and a phosphorous-based epoxy resin.

The cross-linkable resin may further include an inorganic filler selected from the group consisting of silica, alumina, barium sulfate, talc, mud, a mica powder, aluminum hydroxide, magnesium hydroxide, calcium cathonate, magnesium cathonate, magnesium oxide, boron nitride, aluminum borate, barium titanate, calcium titanate, magnesium titanate, bismuth titanate, titan oxide, barium zirconate, and calcium zirconate.

According to another preferred embodiment of the present invention, there is provided a method for manufacturing a prepreg, the method including: providing an inorganic fiber, an organic fiber, or a hybrid fiber obtained by mix-weaving the inorganic fiber and the organic fiber; coating the fiber with a thermally conductive component in a sol state or impregnating the fiber with a thermally conductive component in a sol state; and impregnating the fiber coated with the thermally conductive component or impregnated with the thermally conductive component, with a cross-linkable resin, followed by drying.

The thermally conductive component may be Al₂O₃, BN, AlN, SiO₂, or a mixture thereof.

The cross-linkable resin may be at least one epoxy resin selected from a naphthalene epoxy resin, a bisphenol A epoxy resin, a phenol novolac epoxy resin, a cresole novolac epoxy resin, a rubber modified epoxy resin, and a phosphorous-based epoxy resin.

The cross-linkable resin may further include an inorganic filler selected from the group consisting of silica, alumina, barium sulfate, talc, mud, a mica powder, aluminum hydroxide, magnesium hydroxide, calcium cathonate, magnesium cathonate, magnesium oxide, boron nitride, aluminum borate, barium titanate, calcium titanate, magnesium titanate, bismuth titanate, titan oxide, barium zirconate, and calcium zirconate.

The sol state of the thermally conductive component may be formed by dissolving the thermally conductive component in water, an ether based solvent, a ketone based solvent, or a mixed solvent thereof.

According to still another preferred embodiment of the present invention, there is provided a copper clad laminate obtained by laminating a copper foil on the prepreg as described above, followed by heating, pressurizing, and molding

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a schematic view showing a cross section of a prepreg manufactured according to a preferred embodiment of the present invention; and

FIG. 2 is a schematic view showing a cross section of a prepreg manufactured according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

As described above, a prepreg (PPG) in a substrate is a material for forming an insulating layer, and generally, an inorganic fiber, an organic fiber, or a hybrid fiber obtained by mix-weaving them, may be used as a core of the prepreg. The fibers improve low CTE property of the substrate and thus reduce warpage of the substrate during manufacturing of the substrate, and lower an overall CTE. However, the fibers are limited in being applied to a heat radiating substrate since thermal conductivity of a material itself is low at a thermally conductive part Therefore, in the present invention, there is provided a prepreg including a fiber to which a component having excellent thermally conductivity is added.

In the present invention, the inorganic fiber is a kind of chemical fiber, and is artificially made of an inorganic material. A ceramic fiber, a metal fiber, or the like may belong to the inorganic fiber. In addition, the inorganic fibers may be classified into an alkali glass fiber, a non-alkali glass fiber, a low-dielectric glass fiber, and the like according to the properties thereof. In the present invention, as the inorganic fiber, a glass fiber, an alumina based fiber, a silicon containing ceramic based fiber, or the like may be used, and preferably, the glass fiber may be used.

The organic fiber is a kind of chemical fiber, and is artificially made of an organic polymer material. The organic fibers are classified into a regenerated fiber, a semi-synthetic fiber, a synthetic fiber, and the like. In the present invention, a super fiber, such as, a carbon fiber, a poly-para-phenylenebenzoatebisoxazole (PBO) fiber, a thermotropic liquid crystal polymer fiber, a lysotropic liquid crystal polymer fiber, an aramid fiber, a polypyridobismidazole (PIPD) fiber, a polybenzothiazole (PBZT) fiber, a polyarylate (PAR) fiber or the like, may be used as the organic fiber.

In addition, in the present invention, a hybrid fiber obtained by weaving the inorganic fiber and the organic fiber may be used However, for easy illustration of the present invention, the “glass fiber” is designated as a representative of the fibers, and hereinafter the present invention will be described based on this.

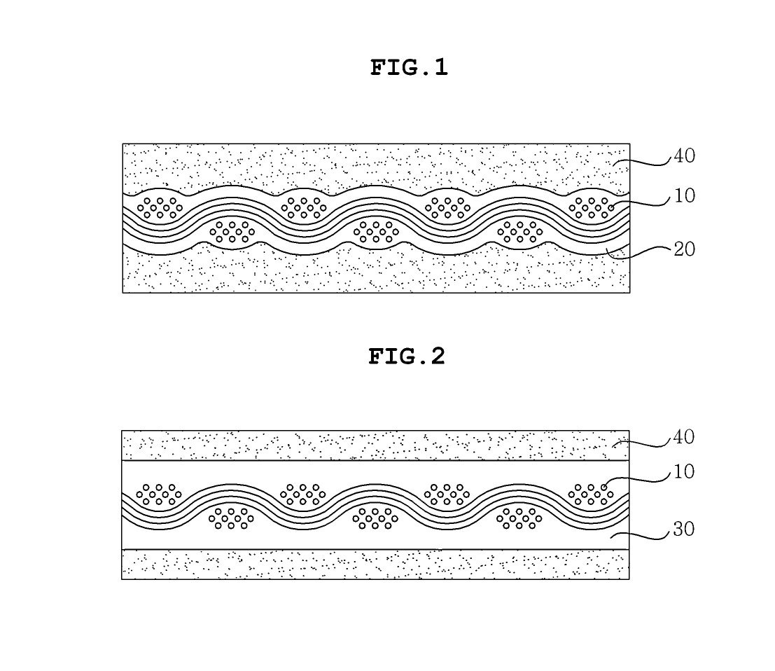

Referring to FIGS. 1 and 2, in the present invention, before manufacturing a PPG for a substrate after preparing a glass fiber 10, the glass fiber 10 is coated with a thermally conductive material 20 in a sol state or the glass fiber 10 is impregnated with a thermally conductive material 30 in a sol state, and then an insulating layer 40 including a cross-linkable resin is formed thereon. In the case where the glass fiber is directly used without being coated with the thermally conductive material, an insulating layer having relatively low thermal conductivity is formed due to low thermal conductivity of the glass fiber at the time of actually manufacturing an insulating layer PPG for heat radiation. Therefore, after alumina (Al₂O₃), BN, AlN, SiO₂, or a mixture thereof, having excellent thermal conductivity, is made into a sol state, and then coated on the glass fiber, or this thermally conductive material is linearly dispersed in a predetermined resin, and then coated on the glass fiber, the thus obtained glass fiber is used as a core at the time of preparing an insulator, thereby improve a low CTE of the substrate itself and thermal conductivity performance of the PPG for heat radiation can be improved.

Water, ethers, ketones, and the like may be used as a solvent for forming the sol type, but is not limited thereto. As a coating method, a dipping method may be generally used, but in some cases, a spray method may be used. The coating thickness after completing the coating and then volatilizing the solvent may be preferably 100 nm˜10 μm. If the coating thickness is below 10 nm, workability may be deteriorated, and thermal conductivity may be less improved. In order to form a coating thickness of above 10 μm, it is necessary to increase viscosity of a slurry containing the solvent or perform coating several times, which causes inconvenience in the process.

Meanwhile, the prepreg in the present invention may include a cross-linkable resin. In addition, the cross-linkable resin may further include an inorganic filler in order to improve electrical characteristics and thermal characteristics of the prepreg, and may further include a solvent in order to be suitable for impregnation.

In the present invention, the cross-linkable resin may be at least one selected from the group consisting of an epoxy resin, a bismaleide triazine (BT) resin, and an imide resin, and preferably an epoxy resin, a resin containing a mesogen group, or an oligomer. These resins can have a synergy effect due to high thermal conductivity thereof, themselves.

Examples of the epoxy resin usable in the present invention may preferably include a bisphenol A epoxy resin, a bisphenol F epoxy resin, a bisphenol S epoxy resin, a phenol novolac epoxy resin, an alkylphenol novolac epoxy resin, a biphenyl epoxy resin, an aralkyl epoxy resin, a dicyclopentadiene epoxy resin, a naphthalene epoxy resin, a naphtol epoxy resin, an epoxy resin of a condensate of phenol and aromatic aldehyde having a phenolic hydroxyl group, a biphenylaralkyl epoxy resin, a fluorene epoxy resin, a xanthene epoxy resin, a triglycidyl isocianurate resin, a rubber modified epoxy resin, and a phosphorus based epoxy resin. Preferable are the naphthalene epoxy resin, bisphenol A epoxy resin, phenol novolac epoxy resin, cresol novolac epoxy resin, rubber modified epoxy resin, and phosphorous based epoxy resin. One kind or two or more kinds of epoxy resins may be mixed for use.

In the cross-linkable resin, the use amount of the epoxy resin is preferably 10 to 90 wt %. If the use amount thereof is below 5 wt %, handling property may be deteriorated. If above 90 wt %, the added amount of other components is relatively small, and thus, the dissipation factor, dielectric constant, and coefficient of thermal expansion may be decreased.

The cross-linkable resin according to the present invention may include, selectively, include a hardener, for process efficiency. The hardener is at least one selected from amide based hardeners, polyamine based hardeners, acid anhydride hardeners, phenol novolac hardeners, polymercaptan hardeners, tertiary amine hardeners, and imidazole hardeners, but is not particularly limited thereto. The use amount of the hardener is preferably 0.1 to 3 wt %. If the content thereof is below 0.1 wt %, high-temperature hardening may be less done or the hardening rate may be decreased. If above 3 wt %, the hardening rate is too high, application thereof to the process may be difficult or storage stability thereof may be deteriorated, and an unreacted hardener may remain, which causes an increase in absorption ratio of the insulating film or the prepreg, resulting in deteriorating electrical characteristics.

The cross-linkable resin according to the present invention may selectively include an inorganic filler in order to lower the coefficient of thermal expansion (CTE) of the epoxy resin and enhance adhesive strength with the metal. The inorganic filler lowers the coefficient of thermal expansion, and the content of the inorganic filler based on the cross-linkable resin need not to be particularly limited, but the inorganic filler may be used in the range of 10 to 90 wt %. If the content thereof is below 10 wt %, the dissipation factor may be lowered and the coefficient of thermal expansion may be increased. If above 90 wt %, adhesive strength may be deteriorated.

Specific examples of the inorganic filler may include silica, alumina, barium sulfate, talc, mud, a mica powder, aluminum hydroxide, magnesium hydroxide, calcium cathonate, magnesium cathonate, magnesium oxide, boron nitride, aluminum borate, barium titanate, calcium titanate, magnesium titanate, bismuth titanate, titan oxide, barium zirconate, calcium zirconate, and the like, which may be used alone or in combination of two or more thereof. Particularly preferable is silica having a low dielectric dissipation factor.

In addition, if the inorganic filler has an average particle size of 5 μm or greater, it is difficult to stably form a fine pattern when a circuit pattern is formed by using a conductor layer. Hence, the average particle size of the inorganic filler is preferably 5 μm or smaller. In addition, the inorganic filler is preferably surface-treated with a surface treating agent such as a silane coupling agent or the like, in order to improve moisture resistance. More preferable is silica having a diameter of 0.05 to 2 μm.

The cross-linkable resin of the present invention may perform efficient hardening by including a hardening accelerant. Examples of the hardening accelerant used in the present invention may be a metal based hardening accelerant, an imidazole based hardening accelerant, an amine based hardening accelerant, and the like, and one or a combination of two or more thereof may be added in a general amount, used in the art.

Examples of the metal based hardening accelerant may include, but are not particularly limited to, organic metal complexes and organic metal salts of a metal, such as, cobalt, copper, zinc, iron, nickel, manganese, tin, or the like. Specific examples of the organic metal complex may include organic cobalt complexes such as cobalt (II) acetylacetonate, cobalt (III) acetylacetonate, and the like, organic copper complexes such as copper (II) acetylacetonate and the like, organic zinc complexes such as zinc (II) acetylacetonate and the like, organic iron complexes such as iron (III) acetylacetonate and the like, organic nickel complexes such as nickel (II) acetylacetonate and the like, and organic manganese complexes such as manganese (II) acetylacetonate and the like. Examples of the organic metal salt may include zinc octylate, tin octylate, zinc naphthenate, cobalt naphthenate, tin stearate, zinc stearate, and the like. As the metal based hardening accelerator, preferable are cobalt (II) acetylacetonate, cobalt (III) acetylacetonate, zinc (II) acetylacetonate, zinc naphthenate, and iron (III) acetylacetonate, and more preferable are cobalt (II) acetylacetonate and zinc naphthenate, in view of hardening property and solubility in solvent. One kind or two or more kinds of metal based hardening accelerants may be used in combination.

Examples of the imidazole based hardening accelerant may include, but are not particularly limited to, imidazole compounds, such as, 2-methyl imidazole, 2-undecyl imidazol, 2-heptadecyl imidazole, 1,2-dimethyl imidazole, 2-ethyl-4-methyl imidazole, 1,2-dimethyl imidazole, 2-ethyl-4-methyl imidazole, 2-phenyl imidazole, 2-phenyl-4-methyl imidazole, 1-benzyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undencyl imidazolium trimellitate, 1-cyanoethyl-2-phenyl imidazolium trimellitate, 2,4-diamino-6-[2′-methyl imidazolyl-(1′)]ethyl-s-triazine, 2,4-diamino-6-[2′-undecyl imidazolyl-(1′)]-ethyl-s-triazine, 2,4-diamino-6-[2′-ethyl-4′-methyl imidazolyl-(1′)]ethyl-s-triazine, methyl imidazolyl-(1′)]ethyl-s-triazine isocyanuric acid adduct, 2-phenyl imidazole isocyanuric acid adduct, 2-phenyl-4,5-dihydroxymethyl imidazole, 2-phenyl-4-methyl-5-hydroxy methyl imidazole, 2,3-dihydroxy-1H-pyrrolo[1,2-a]benz imidazole, 1-dodecyl-2-methyl-3-benzyl imidazolium chloride, 2-methyl imidazolin, 2-phenyl imidazolin, and the like, and adduct bodies of the imidazole compounds and epoxy resins. One kind or two or more kinds of imidazole hardening accelerants may be used in combination.

Examples of the amine based hardening accelerant may include, but are not particularly limited to, amine compounds, for example, trialkyl amines such as trimethylamine, tributylamine, and the like, 4-dimethylaminopyridine, benzyldimethyl amine, 2,4,6-tris(dimethylaminomethyl)phenol, 1,8-diazabicyclo(5,4,0)-undecene (hereinafter, referred to as DBU), and the like. One kind or two or more kinds of amine based hardening accelerants may be used in combination.

The cross-linkable resin of the present invention may selectively further include a thermoplastic resin in order to improve film property thereof or improve mechanical property of the hardened material. Examples of the thermoplastic resin may include a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, a polyester resin, and the like. These thermoplastic resins may be used alone or in mixture of two or more. The average weight molecular weight of the thermoplastic resin is preferably in the range of 5,000 to 200,000. If the average weight molecular weight thereof is below 5,000, effects of improving film formability and mechanical strength may not be sufficiently exhibited. If above 200,000, compatibility with the epoxy resin may not be sufficient; surface unevenness after hardening becomes larger, and high-density fine wirings are difficult to form. The weight molecular weight is measured at a column temperature of 40° C. by using, specifically, LC-9A/RID-6A from the Shimadzu Company as a measuring apparatus, Shodex K-800P/K-804L/K-804L from the Showa Denko Company as a column, and chloroform (CHCl₃) as a mobile phase, and then calculated by using a calibration curve of standard polystyrene.

In the case when a thermoplastic resin is blended with the cross-linkable resin, the content of the thermoplastic resin in the cross-linkable resin is, but is not particularly limited to, preferably 0.1 to 10 wt %, and more preferably 1 to 5 wt %, based on 100 wt % of non-volatile matter in the cross-linkable composition. If the content of the thermoplastic resin is below 0.1 wt %, the improvement effect of film formability or mechanical strength may not be exhibited. If above 10 wt %, molten viscosity may be increased and surface roughness of an insulating layer after a wet roughening process may be increased.

The insulating cross-linkable resin according to the present invention is mixed in the presence of an organic solvent. Examples of the organic solvent, considering solubility and miscibility of the resin and other additives used in the present invention, may include 2-methoxy ethanol, acetone, methyl ethyl ketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethyl formamide, and dimethyl acetamide, but are not particularly limited thereto.

The cross-linkable resin according to the present invention has viscosity in the range of 700 to 1500 cps, which is suitable for preparing the prepreg, and is characterized by maintaining sticking property appropriate at room temperature. The viscosity of the cross-linkable resin may be controlled by varying the content of the solvent. Other non-volatile components excluding the solvent account for 30 to 70 wt % based on the cross-linkable resin. If the viscosity of the cross-linkable resin is out of the above range, it may be difficult to form the prepreg, or it may be troublesome to mold a member even though the prepreg is formed.

Besides, as necessary, the present invention may further include additives, such as, a softener, a leveling agent, a plasticizer, an antioxidant, a flame retardant, a flame retardant aid, a lubricant, an antistatic agent, a colorant, a heat stabilizer, a light stabilizer, a UV absorbent, a coupling agent and/or a sedimentation inhibitor, known in the art, by those skilled in the art within the technical scope of the present invention.

The cross-linkable resin may be manufactured into a semisolid-phase dry film by any general method known in the art. For example, the resin may be manufactured into a film type by using a roll coater, a curtain coater, or the like, and then dried. Then, the film is applied onto a substrate, to thereby be used as an insulating layer (or an insulating film) or prepreg when the multilayer printed circuit board is manufactured in a build-up manner. This insulating film or prepreg has a low coefficient of thermal expansion (CTE) of 50 ppm/° C. or lower.

The prepreg is manufactured by coating or impregnating a reinforcing member such as, the inorganic fiber, organic fiber, or hybrid fiber obtained by mix-weaving them, with the thermally conductive component, and then impregnating the fiber with the cross-linkable resin, followed by drying.

Examples of an impregnating method may be a dip coating method, a roll coating method, and the like. Here, the glass fiber may have a thickness of 5 to 200 μm. The cross-linkable resin may have about 0.4 to 3 parts by weight based on 1 part by weigh of the reinforcing member. In the case where impregnation is performed within the above range, adhesion between prepregs is excellent at the time of using two or more prepregs, and mechanical strength and dimensional stability of the prepreg is excellent. The hardening process may be performed at a temperature of about 150° C. to about 350° C. As such, heat treatment may be possible even at a low temperature, and thus, a printed circuit board can be manufactured.

The prepreg may be combined with copper. That is, after the cross-linkable resin of the present invention is impregnated with the reinforcing agent and then subjected to a B-stage heat treatment process, to thereby manufacture a prepreg, the thus manufactured prepreg is positioned on a copper foil, and then a heat treatment is performed thereon. When the solvent is removed and heat treatment is performed, there is manufactured a member where copper and prepreg are combined with each other. In order to evaporate the solvent, heating is performed under the reduced pressure, or ventilation or the like may be employed. Examples of a coating method may be a roller coating method, a dip coating method, a spray coating method, a spin coating method, a curtain coating method, a slit coating method, a screen printing method, and the like.

According to another preferred embodiment, a copper clad laminate (CCL) or a flexible CCL may be manufactured by laminating a copper foil on the prepreg, and performing heating, pressurizing, and molding in a conventional manner.

Hereinafter, the present invention will be described in more detail with reference to the following examples, but the scope of the present invention is not limited thereto.

### EXAMPLE 1

100 g of a bisphenol A epoxy resin “YD-011” (epoxy equivalent 469, manufactured by the KUKDO Chemical Company) and 4.5 g of a dispersant (BYK-110, manufactured by the BYK Company) were dissolved in 83 g of methylethylketone (MEK), and 162.5 g of silica was input thereto. The resultant materials were linearly dispersed by using a homo-mixer at a rate of 2000 rpm for 30 minutes, and then dispersed by using a beads-mill for 1 hour. 2 g of 2-ethyl-4-methyl imidazole as a hardener was dissolved in the dispersion composition to prepare a resin varnish. The resin varnish was coated on a polyethyleneterephthalate film having a thickness of about 38 μm by using a bar coater, and then dried for 10 minutes so that the resin has a thickness after drying of about 40 μm.

### EXAMPLE 2

A BN 30 wt % sol solution dispersed in an ether based solvent was coated on a surface of a glass fiber (manufactured by the Nittobo Company, 2116) in a spray manner, and then the fiber (coating thickness: about 1 μm) dried in an oven was impregnated with the varnish prepared in Example 1. The glass fiber impregnated with the varnish was allowed to pass through a heating zone of 200° C., and then semi-hardened, thereby obtaining a prepreg. Here, the weight of the polymer was 54 wt % based on the total weight of the prepreg.

### COMPARATIVE EXAMPLE 1

A glass fiber (manufactured by the Nittobo Company, 2116) was impregnated with the varnish prepared in Example 1. The glass fiber impregnated with the varnish was allowed to pass through a heating zone of 200° C., and then semi-hardened, thereby obtaining a prepreg. Here, the weight of the polymer was 54 wt % based on the total weight of the prepreg.

Evaluation on Thermal Characteristics

The coefficient of thermal expansion (CTE) of each sample of the prepregs manufactured according to the Example 2 and Comparative Example 1 was measured by using a thermomechanical analyzer (TMA), and the results were tabulated in Table 1 below.

Evaluation on Peeling Strength of Copper Foil

A 1 cm-width copper foil was peeled from a surface of a copper clad laminate, and then the peeling strength of the copper foil was measured by using a tensile strength measuring instrument (Universal Testing Machine (UTM) /KTW100), and the results were shown in Table 1 below (90° peeling test, cross head rate: 50 mm/min).

Thermal Conductivity

Thermal conductivity was measured by using a thermal conductivity instrument (Holometrix TCHM-LT), and the results were tabulated in Table 1 below.

TABLE 1

| Classification | Unit | Example 1 | Comparative Example 1 |
|---|---|---|---|
| Thermal Conductivity | W/mK | 3 | 1 |
| Breakdown Voltage | AC | 3.5 | 3.8 |
| | kV | | |
| Coefficient of Thermal | ppm/ | 15~20 | 15~19 |
| Expansion | ° C. | | |
| Peeling Strength | kgf/cm | 1.5 | 1.6 |

As shown in Table 1 above, the prepreg according to the present invention had thermal and mechanical properties, such as a coefficient of thermal expansion, peeling strength, and breakdown voltage, similar to those of the general prepreg, but had three times the thermal conductivity, which exhibits excellent heat radiation characteristics, as compared with the general prepreg.

As set forth above, the prepreg and the copper clad laminate according to the present invention can maintain a low coefficient of thermal expansion and a high modulus of elasticity and have excellent heat radiation property.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A prepreg, comprising:
an inorganic fiber, an organic fiber, or a hybrid fiber obtained by mix-weaving the inorganic fiber and the organic fiber, coated with a thermally conductive component or impregnated with a thermally conductive component; and
a cross-linkable resin for impregnating the fiber therewith.

2. The prepreg as set forth in claim 1, wherein the thermally conductive component is Al₂O₃, BN, AlN, SiO₂, or a mixture thereof.

3. The prepreg as set forth in claim 1, wherein a coating thickness is 100 nm-10 μm.

4. The prepreg as set forth in claim 1, wherein the inorganic fiber is a glass fiber.

5. The prepreg as set forth in claim 1, wherein the organic fiber is at least one of a carbon fiber, a poly-para-phenylenebenzoatebisoxazole fiber, a thermotropic liquid crystal polymer fiber, a lysotropic liquid crystal polymer fiber, an aramid fiber, a polypyridobismidazole fiber, a polybenzothiazole fiber, and a polyarylate fiber.

6. The prepreg as set forth in claim 1, wherein the cross-linkable resin is at least one epoxy resin selected from a naphthalene epoxy resin, a bisphenol A epoxy resin, a phenol novolac epoxy resin, a cresole novolac epoxy resin, a rubber modified epoxy resin, and a phosphorous-based epoxy resin.

7. The prepreg as set forth in claim 6, wherein the cross-linkable resin further includes an inorganic filler selected from the group consisting of silica, alumina, barium sulfate, talc, mud, a mica powder, aluminum hydroxide, magnesium hydroxide, calcium carbonate, magnesium cathonate, magnesium oxide, boron nitride, aluminum borate, barium titanate, calcium titanate, magnesium titanate, bismuth titanate, titan oxide, barium zirconate, and calcium zirconate.

8. A method for manufacturing a prepreg, the method comprising:
providing an inorganic fiber, an organic fiber, or a hybrid fiber obtained by mix-weaving the inorganic fiber and the organic fiber;
coating the fiber with a thermally conductive component in a sol state or impregnating the fiber with a thermally conductive component in a sol state; and
impregnating the fiber coated with the thermally conductive component or impregnated with the thermally conductive component, with a cross-linkable resin, followed by drying.

9. The method as set forth in claim 8, wherein the thermally conductive component is Al₂O₃, BN, AlN, SiO₂, or a mixture thereof.

10. The method as set forth in claim 8, wherein the cross-linkable resin is at least one epoxy resin selected from a naphthalene epoxy resin, a bisphenol A epoxy resin, a phenol novolac epoxy resin, a cresole novolac epoxy resin, a rubber modified epoxy resin, and a phosphorous-based epoxy resin.

11. The method as set forth in claim 10, wherein the cross-linkable resin further includes an inorganic filler selected from the group consisting of silica, alumina, barium sulfate, talc, mud, a mica powder, aluminum hydroxide, magnesium hydroxide, calcium carbonate, magnesium cathonate, magnesium oxide, boron nitride, aluminum borate, barium titanate, calcium titanate, magnesium titanate, bismuth titanate, titan oxide, barium zirconate, and calcium zirconate.

12. The method as set forth in claim 8, wherein the sol state of the thermally conductive component is formed by dissolving the thermally conductive component in water, an ether based solvent, a ketone based solvent, or a mixed solvent thereof.

13. A copper clad laminate obtained by laminating a copper foil on the prepreg as set forth in claim 1, followed by heating, pressurizing, and molding
